(19) United States
(12) Patent Application Publication
(10) Pub. No.: US 2015/0138726 A1
(43) Pub. Date: May 21, 2015

(54) ELASTOMERIC MEMBER AND A METHOD FOR ARRANGING COMPONENTS

(71) Applicant: NOKIA CORPORATION, Espoo (FI)

(72) Inventor: Mika Suonmaa, Palkane (FI)

(21) Appl. No.: 14/401,359

(22) PCT Filed: May 30, 2012
(86) PCT No.: PCT/FI2012/050527

§ 371 Date: Nov. 14, 2014

(51) Int. Cl. H05K 7/14; G06F 1/16

(52) U.S. Cl. CPC H05K 7/14; G06F 1/1613
USPC 361/679.55; 29/592.1; 248/213.2; 248/310

(57) ABSTRACT

An elastomeric member (13) and method wherein the elastomeric member (13) comprises a plurality of grooves (31) wherein the grooves (31) are configured to receive edge portions of a plurality of components (14) of an electronic apparatus (1).

### TECHNOLOGICAL FIELD

Embodiments of the present disclosure relate to an elastomeric member and method. In particular, they relate to an elastomeric member and method for assembling an electronic apparatus using the elastomeric member.

### BACKGROUND

Electronic apparatus typically comprise a plurality of components. The plurality of components may need to be coupled together or coupled to an external casing. It may be useful to couple the components together in a simple and cost effective manner.

### BRIEF SUMMARY

According to some, but not necessarily all, embodiments of the disclosure there may be provided an elastomeric member comprising a plurality of grooves wherein the grooves are configured to receive edge portions of a plurality of components of an electronic apparatus.

In some embodiments the elastomeric member may be configured to hold the components in a stacked configuration.

In some embodiments the elastomeric member may be configured to bias the components towards each other.

In some embodiments the components may comprise internal components of the electronic apparatus.

In some embodiments the elastomeric member may be configured to extend around the perimeter of the components. The elastomeric member may be configured to surround the perimeter of the components.

In some embodiments the elastomeric member may be configured to be secured to an outer casing of the electronic apparatus. The elastomeric member may comprise a recess configured to secure the elastomeric member to an outer casing of the electronic apparatus.

In some embodiments the elastomeric member may be configured to hold the plurality of components in position within the outer casing of the electronic apparatus.

In some embodiments the elastomeric member may comprise a ribbed outer surface.

According to some, but not necessarily all, embodiments of the disclosure there may be provided an apparatus comprising a plurality of components and an elastomeric member as described above.

According to some, but not necessarily all, embodiments of the disclosure there may be provided a method comprising: arranging a plurality of components of an electronic apparatus within a plurality of grooves of an elastomeric member, wherein the grooves are configured to receive edge portions of the plurality of components.

In some embodiments the method may comprise arranging the components in a stacked configuration within the grooves of the elastomeric member.

In some embodiments the elastomeric member may be configured to bias the components towards each other.

In some embodiments the components may comprise internal components of the electronic apparatus.

In some embodiments the elastomeric member may be configured to extend around the perimeter of the components. The elastomeric member may be configured to surround the perimeter of the components.

In some embodiments the method may comprise securing the elastomeric member to an outer casing of the electronic apparatus.

In some embodiments the elastomeric member may comprise a recess configured to secure the elastomeric member to an outer casing of the electronic apparatus.

In some embodiments the elastomeric member may be configured to hold the plurality of components in position within the outer casing of the electronic apparatus.

In some embodiments the elastomeric member may comprise a ribbed outer surface.

The apparatus may be for wireless communication.

### BRIEF DESCRIPTION

For a better understanding of various examples of embodiments of the present disclosure reference will now be made by way of example only to the accompanying drawings in which:

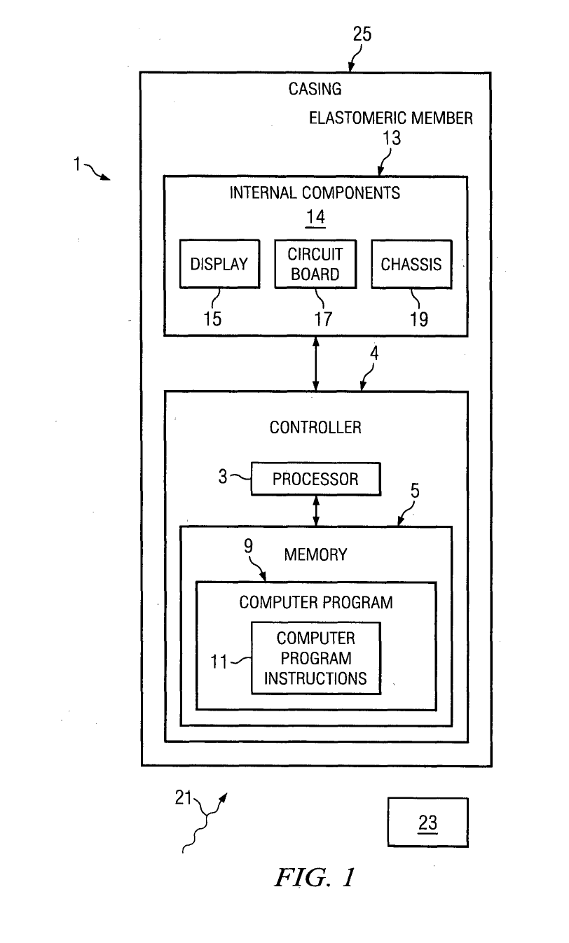

FIG. 1 illustrates an apparatus according to an exemplary embodiment of the disclosure;

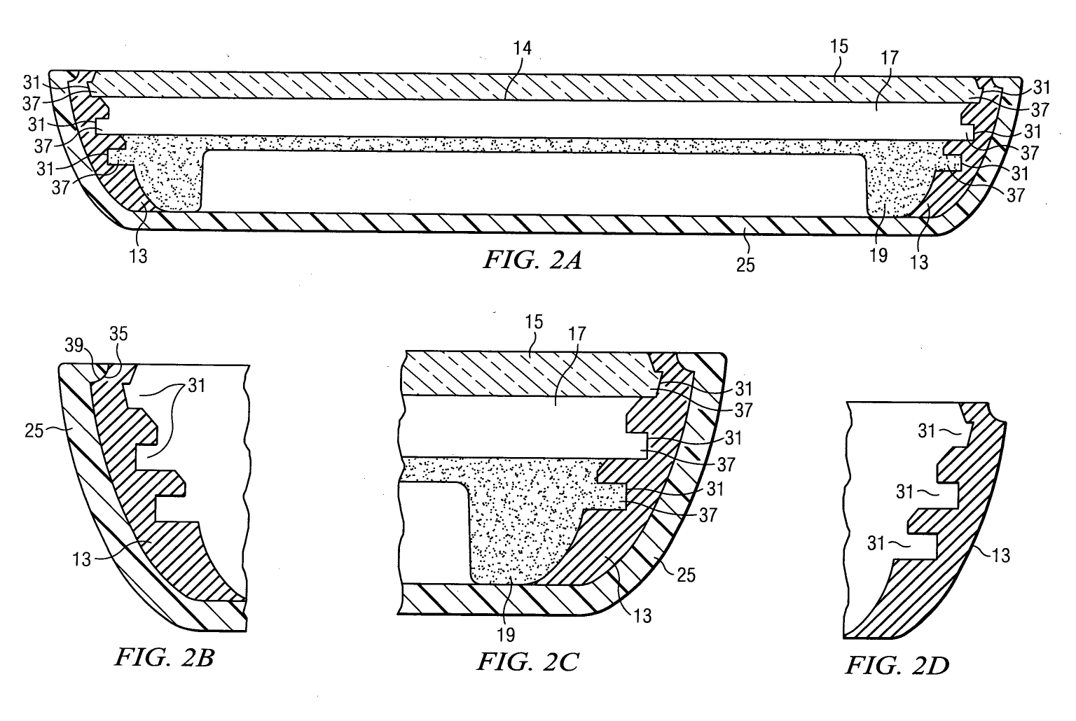

FIGS. 2A to 2D illustrate a cross section of an apparatus comprising an elastomeric member according to an exemplary embodiment of the disclosure;

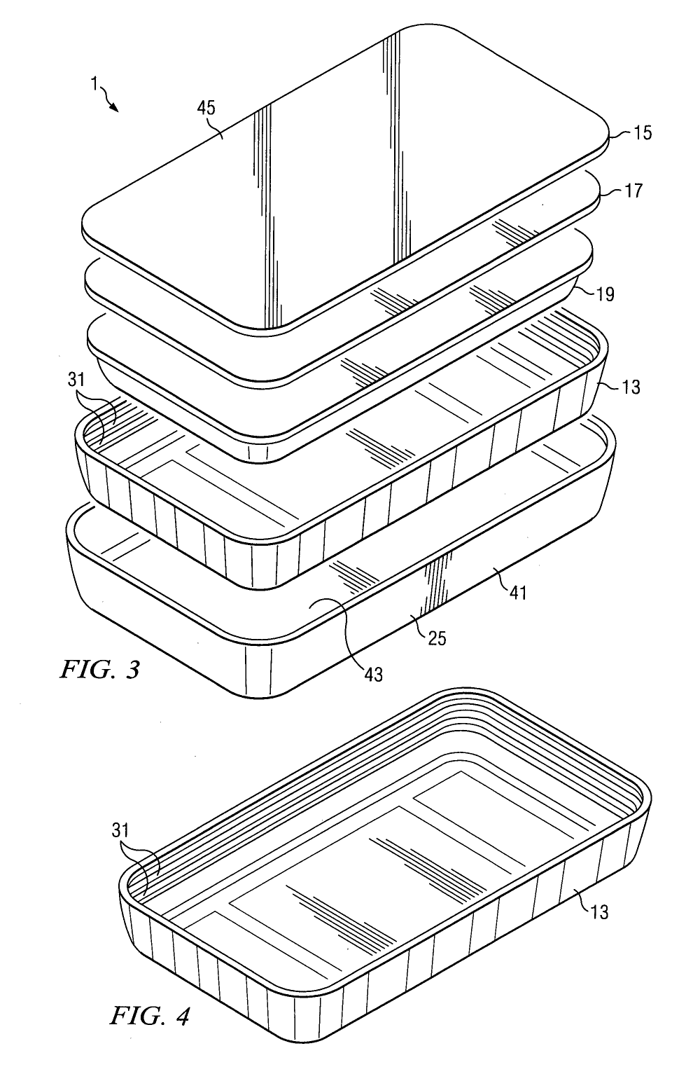

FIG. 3 illustrates an exploded view of an elastomeric member and components of an apparatus according to an exemplary embodiment of the disclosure; and

FIG. 4 illustrates an elastomeric member according to an exemplary embodiment of the disclosure.

### DETAILED DESCRIPTION

The Figures illustrate an elastomeric member 13 and method wherein the elastomeric member 13 comprises a plurality of grooves 31 wherein the grooves 31 are configured to receive edge portions of a plurality of components 14 of an electronic apparatus 1.

FIG. 1 schematically illustrates an apparatus 1 according to an embodiment of the disclosure. The apparatus 1 may be an electronic apparatus. The apparatus 1 may be, for example, a mobile cellular telephone, a personal computer, a lap top, a tablet computer a personal digital assistant, a music player, or any other apparatus that may comprise a plurality of components. In some embodiments of the disclosure the apparatus 1 may be a handheld apparatus 1 which may be carried in a user's hand, handbag or pocket of their clothing for example.

Only features referred to in the following description are illustrated in FIG. 1. It should, however, be understood that the apparatus 1 may comprise additional features that are not illustrated. For example, in embodiments of the disclosure where the apparatus 1 is a mobile cellular telephone, the apparatus 1 may also comprise features such as a transmitter and receiver configured to enable wireless communication and a user interface configured to enable a user to control the apparatus 1.

The apparatus 1 illustrated in FIG. 1 comprises: a controller 4 and a plurality of components 14. In the exemplary embodiment of FIG. 1 the controller 4 and the plurality of components 14 may be contained within a casing 25.

The plurality of components 14 may comprise structural or functional components of the electronic apparatus 1. For example in some embodiments of the disclosure the internal components 14 may comprise means for providing structural support to the apparatus 1. In such embodiments the internal components may comprise a chassis 19 or frame or any other suitable structure.

In some embodiments of the disclosure the internal components 14 may comprise a substrate such as a printed wiring board 17. In some embodiments of the disclosure electronic components and/or circuitry may be mounted on the printed wiring board 17. In some embodiments of the disclosure the controller 4 may be mounted on or coupled to the printed wiring board 17. The printed wiring board may comprise a rigid or flexible substrate. The printed wiring board 17 may comprise one or more layers of a multi-layered printed wiring board 17.

In some embodiments of the disclosure the internal components may comprise a display 15 such as a touch sensitive display. The touch sensitive display 15 may enable a user to input information into the apparatus 1 and may enable information to be displayed or otherwise provided to a user. In some other embodiments of the disclosure other user input devices may be provided instead of or in addition to the touch sensitive display 15. For example, in other embodiments of the disclosure the user input device may comprise one or more mechanically and/or electrically switched keys. In some embodiments more than one key may be provided in a keyboard or keypad.

In the apparatus 1 schematically illustrated in FIG. 1 an elastomeric member 13 is provided around the internal components 14. Exemplary embodiments of the elastomeric member 13 are illustrated in FIGS. 2A to 4 and described in more detail below.

As mentioned above, the apparatus 1 illustrated in FIG. 1 also comprises a casing 25. The casing 25 provides an external housing for the apparatus 1. The casing 25 may form an outer surface of the apparatus 1. The casing 25 may provide protection for the components 14 of the apparatus 1. For example, the casing 25 may protect the components 14 of the apparatus 1 from atmospheric conditions such as moisture or temperature variations. The casing 25 may also be configured to protect the components 14 of the apparatus 1 from mechanical shocks.

The components 14 of the apparatus 1, which are illustrated schematically in FIG. 1, may be contained within the housing 25. The internal components 14 may be at least partially contained within the casing 25. Some of the internal components 14 may be entirely contained within the casing 25 so that the casing 25 provides a barrier between the internal component 14 and the user or the external environment.

In some of the embodiments some of the internal components 14 may be partially contained within the casing 25. In such embodiments a part of the component may be contained within the casing 25 and part of the component may form part of the outer surface of the apparatus 1. For example, a display 15 may comprise a screen which may form part of the outer surface of the apparatus 1. The screen may form part of the outer surface of the apparatus 1 so that it may be touched by a user of the apparatus 1 and as such is not contained within the casing 25. The display 15 may also comprise other components such as a driver which may be contained within the casing 25 so it cannot be touched by a user.

In some embodiments of the disclosure the internal components 14 may be coupled together. In some embodiments, at least some of the internal components 14 may be functionally coupled together, for example circuitry mounted on the printed printed wiring board 17 may be coupled to the display 15.

In some embodiments of the disclosure at least some of the internal components 14 may be structurally coupled together so that some of the internal components 14 may be touching or physically connected together.

In the exemplary embodiment illustrated in FIG. 1 the controller 4 may provide means for controlling the apparatus 1. The controller 4 may be implemented using instructions that enable hardware functionality, for example, by using executable computer program instructions 11 in a general-purpose or special-purpose processor 3 that may be stored on a computer readable storage medium 23 (e.g. disk, memory etc) to be executed by such a processor 3.

The controller 4 may be configured to control the apparatus 1 to perform a plurality of different functions. For example, where the apparatus 1 is a mobile cellular telephone the controller 4 may be configured to control the apparatus 1 to make and receive telephone calls and also to perform other functions such as send messages or access communication networks such as local area networks or the internet.

The memory 5 may be configured to store a computer program 9 comprising computer program instructions 11 that control the operation of the apparatus 1 when loaded into the processor 3. The processor 3 may be configured to read the memory 5 to load and execute the computer program 9.

The computer program instructions 11 may provide computer readable program means configured to control the apparatus 1. The computer program 9 may arrive at the apparatus 1 via any suitable delivery mechanism 21. The delivery mechanism 21 may be, for example, a computer-readable storage medium, a computer program product 23, a memory device, and a record medium such as a CD-ROM or DVD, an article of manufacture that tangibly embodies the computer program 9. The delivery mechanism may be a signal configured to reliably transfer the computer program 9. The apparatus 1 may propagate or transmit the computer program 9 as a computer data signal.

Although the memory 5 is illustrated as a single component it may be implemented as one or more separate components some or all of which may be integrated/removable and/or may provide permanent/semi-permanent/dynamic/cached storage.

References to ‘computer-readable storage medium’, ‘computer program product’, ‘tangibly embodied computer program’ etc. or a ‘controller’, ‘computer’, ‘processor’ etc. should be understood to encompass not only computers having different architectures such as single/multi-processor architectures and sequential (e.g. Von Neumann)/parallel architectures but also specialized circuits such as field-programmable gate arrays (FPGA), application integration specific circuits (ASIC), signal processing devices and other devices. References to computer program, instructions, code etc. should be understood to encompass software for a programmable processor or firmware such as, for example, the programmable content of a hardware device whether instructions for a processor, or configuration settings for a fixed-function device, gate array or programmable logic device etc.

FIGS. 2A to 2D illustrate a cross section of an apparatus 1 comprising an elastomeric member 13 according to an exemplary embodiment of the disclosure.

FIG. 2A illustrates a cross section of the apparatus 1. The apparatus 1 may be an apparatus 1 as schematically illustrated in FIG. 1. The apparatus 1 comprises a plurality of internal components 14, an elastomeric member 13 and a casing 25. In the exemplary embodiment of FIG. 2A the plurality of internal components 14 comprises a chassis 19, a printed wiring board 17 and a display 15. It is to be appreciated that in other embodiments of the disclosure other internal components 14 may be used instead. It is also to be appreciated that the apparatus 1 may comprise only one internal component 14 or more than one internal component 14.

FIG. 2B illustrates a cross section of the casing 25 and elastomeric member 13 in more detail, FIG. 2C illustrates a cross section of the internal components 14 and the elastomeric member 13 in more detail and FIG. 2D illustrates a cross section of the elastomeric member 13 in more detail.

In the exemplary embodiment of FIGS. 2A to 2D the chassis 19, printed wiring board 17 and display 15 are arranged in a stacked configuration. In the stacked configuration the internal components 14 are provided overlaying, or at least partially overlaying, each other. In the stacked configuration the internal components 14 may be provided on top of each other so that the stack extends in a vertical direction. It is to be appreciated that in other embodiments of the disclosure the internal components 14 may be arranged in a different configuration.

In the particular embodiment of FIGS. 2A to 2D the chassis 19 provides a rigid internal frame for the apparatus 1. The printed wiring board 17 is provided overlaying the chassis 19 and the display 15 is provided overlaying the printed wiring board 17. It is to be appreciated that in other embodiments of the disclosure the internal components 14 may be arranged differently or different internal components 14 may be used.

In the exemplary embodiment of FIGS. 2A to 2D the elastomeric member 13 is used to couple the internal components 14 together. The elastomeric member may extend around the edges of the internal components 14. In the particular embodiment illustrated in FIGS. 2A to 2D the elastomeric member 13 is provided between the internal components 14 and the outer casing 25 of the apparatus 1.

The exemplary elastomeric member 13 illustrated in FIGS. 2A to 2D comprises a plurality of grooves 31. The grooves 31 are provided on an inner surface of the elastomeric member 13. The grooves 31 are sized and shaped to receive the edge portions 33 of the internal components 14. In some embodiments of the disclosure the edge portions 33 of the internal components 14 may also be sized and shaped to fit into the grooves 31 of the elastomeric member 13. For example a flange 37 may be provided at the edge of the internal components which may fit into the groove 31. The flange 37 may be thinner than the rest of the internal component 14. This may reduce the thickness of the groove 31 needed.

In the exemplary embodiment of FIGS. 2A to 2D a different groove 31 is provided in the elastomeric member 13 for each of the internal components 14. The internal components 14 are arranged so that each internal component 14 may be received in a different groove 31. In some embodiments each of the grooves 31 may be sized or shaped differently to ensure that the right internal component 14 is provided in the correct groove 31.

In the exemplary embodiment of FIGS. 2A to 2D the grooves 31 are spaced vertically from each other. This may enable the internal components 14 to be arranged in the stacked configuration. The spacing between the grooves 31 may be configured so as to control the relative positions between the internal components.

The elastomeric member 13 may comprises a flexible material which may be configured to return to its original shape if it is deformed. This may cause the elastomeric member 13 to bias the internal components 14 towards each other when they are received within the grooves 31. This may hold the internal components 14 in position relative to each other.

In the exemplary embodiment of FIGS. 2A to 2D the elastomeric member 13 also provides means for securing the elastomeric member 13 to the casing 25. As illustrated in the detail of FIG. 2B the means for securing the elastomeric member 13 to the casing 25 comprises a recessed portion 35 in the elastomeric member 13. The recessed portion 35 may be sized and shaped to receive a projection 39 located on an inner surface of the casing 25. This may enable the casing 25 and the elastomeric member 13 to be held in position relative to each other. This may restrict relative movement between the casing 25 and the elastomeric member 13 and any internal components 14 positioned within the elastomeric member 13.

FIG. 3 illustrates an exploded view of an apparatus 1 comprising an elastomeric member 13 and components 14 according to an exemplary embodiment of the disclosure. The apparatus 1 may be the same as the apparatus 1 of FIG. 1 and FIGS. 2A to 2D.

In the exemplary embodiment of FIG. 3 the internal components 14 comprise a chassis 19, a printed wiring board 17 and a display 15, as described above. In the exemplary embodiment of FIG. 3 the internal components 14 have flat or planar surfaces. Each of the flat or planar surfaces may be configured to overlay the flat or planar surface of the other internal components 13 so that the internal components can be arranged overlaying each other in a stacked configuration.

The apparatus 1 illustrated in FIG. 3 also comprises a casing 25. The exemplary casing 25 illustrated in FIG. 3 comprises a lower surface portion 43 which forms the base of the apparatus 1 and edge portions 41 which extend around the lower surface portion 43. In the exemplary embodiment illustrated in FIG. 3 the lower surface portion 43 comprises an internal surface of the casing 25. The casing 25 forms a housing for the internal components 14.

In the exemplary embodiment illustrated in FIG. 3 the display 15 may provide an upper surface 45 for the casing 25 to complete the casing 25 and protect the rest of the internal components of the apparatus 1. In the exemplary embodiment illustrated in FIG. 3 the upper surface 45 comprises an external surface of the casing 25.

The elastomeric member 13 illustrated in FIG. 3 is configured to be positioned between the inner surface of the casing 25 and the internal components 14. In the exemplary embodiment of FIG. 3 the elastomeric member 13 is configured to extend around the perimeter of the internal components 14. The exemplary elastomeric member 13 illustrated in FIG. 3 is configured to surround the perimeter of the internal components 14. This may provide an unbroken seal around the edges of the internal components 14.

In other embodiments of the disclosure the elastomeric member 13 may extend only partially around the edge of the internal components 14. For example, it may extend only along one of the edges or two or more elastomeric members 13 may be provided which may extend along different edges.

In some exemplary embodiments more than one elastomeric member 13 may be provided. For example, two elastomeric members 13 may be provided. The two elastomeric members 13 may be arranged to extend along opposite edges of the internal components 14. In some embodiments more than two elastomeric members 13 may be provided.

In some embodiments of the disclosure, once the apparatus 1 has been assembled, the elastomeric member 13 may be located entirely within the casing 25 of the apparatus 1. In other embodiments once the apparatus 1 has been assembled, a part of the elastomeric member 13 may form part of the upper surface 45 of the casing 25 between the display 15 and the edge portions 41 of the casing 25. In such embodiments the elastomeric member 13 may act as a seal to prevent the ingress of fluid or dust into the apparatus 1 between the gap between the display 15 and the edge of the casing 25.

FIG. 4 illustrates an elastomeric member 13 according to an exemplary embodiment of the disclosure.

The elastomeric member 13 has a substantially rectangular shape. This may make the elastomeric member 13 illustrated in FIG. 4 suitable for use with substantially rectangular internal components 14. It is to be appreciated that any suitable shape of elastomeric member 13 may be used in other embodiments of the disclosure. The size and shape of the elastomeric member 13 which is used may be determined by the components which it is to hold together.

In the example of FIG. 4 it can be seen that the grooves 31 extend around the inner perimeter of the elastomeric member 13. The grooves 31 may extend around the entire inner perimeter of the elastomeric member 13. This may enable the entire perimeter of an internal component to be received within a groove 31. This may enable internal components 14 to be held securely within the elastomeric member 13. The electronic apparatus 1 may be assembled by arranging each of the internal components 14 into the respective grooves 31.

The elastomeric member 13 illustrated in FIG. 4 also comprises a ribbed portion 51 on the outer surface of the elastomeric member 13. The ribbed portion may reduce the force need to stretch the elastomeric member 13 around the edges of the internal components 14 when the apparatus 1 is being assembled. Once the apparatus 1 has been assembled the ribbed portion 51 may abut the inside of the casing 25.

Embodiments of the disclosure provide a simple mechanism and method for assembling an apparatus 1 such as an electronic apparatus 1. The elastomeric member 13 may be a simple and light weight member. The elastomeric member may be used to hold the internal components 14 in position relative to each other and also the casing 25. This may remove the need for screws or adhesives or other fixing means.

In some embodiments the elastomeric member may comprise a single member 13 which may extend all the way around the edges of the internal components 14. This may reduce the total number of individual elements within the apparatus 1 and so may make the apparatus 1 simpler. This may also act as a seal to protect the internal components 14.

In embodiments where more than one elastomeric member 13 is used this may enable a cheaper apparatus 1 to be provided as the plurality of elastomeric members 13 retain the internal components in position 14 but do not need to extend all the way around the perimeter of the internal components 14.

The elastomeric member 13 also enables an apparatus 1 to be assembled simply by inserting the respective components into the grooves 31 of the elastomeric member 13. This may provide a simple method of assembling and also disassembling the apparatus 1.

Also the elastomeric member 13 may be used to hold a plurality of components 14 in position relative to each other without taking up too much space within the casing 25 of the apparatus 1.

In some embodiments of the disclosure the elastomeric member 13 may also act to cushion the internal components 14 and protect them from damage caused by impact. The elastomeric member 13 may also protect some of the internal components 14 from damage due to fluid ingress or dust contacting the components.

In the embodiments described above the term “coupled” means operationally coupled and any number or combination of intervening elements may exist between coupled components (including no intervening elements).

Although embodiments of the present disclosure have been described in the preceding paragraphs with reference to various examples, it should be appreciated that modifications to the examples given can be made without departing from the scope of the disclosure as claimed.

Features described in the preceding description may be used in combinations other than the combinations explicitly described.

Although functions have been described with reference to certain features, those functions may be performable by other features whether described or not.

Although features have been described with reference to certain embodiments, those features may also be present in other embodiments whether described or not.

Whilst endeavoring in the foregoing specification to draw attention to those features of the disclosure believed to be of particular importance it should be understood that the Applicant claims protection in respect of any patentable feature or combination of features hereinbefore referred to and/or shown in the drawings whether or not particular emphasis has been placed thereon.

1-21. (canceled)

22. An elastomeric member comprising a plurality of grooves configured to receive edge portions of a plurality of components of an electronic apparatus.

23. An elastomeric member as claimed in claim 22 wherein the elastomeric member is configured to hold the plurality of components in a stacked configuration.

24. An elastomeric member as claimed in claim 22 wherein the elastomeric member is configured to bias the plurality of components towards each other.

25. An elastomeric member as claimed in claim 22 wherein the plurality of components comprise at least some internal components of the electronic apparatus.

26. An elastomeric member as claimed in claim 22 wherein the elastomeric member is configured to extend around the perimeter of the components.

27. An elastomeric member as claimed in claim 26 wherein the elastomeric member is configured to surround the perimeter of the components.

28. An elastomeric member as claimed in claim 22 wherein the elastomeric member is configured to be secured to a casing of the electronic apparatus.

29. An elastomeric member as claimed in claim 22 wherein the plurality of grooves are configured to hold the plurality of components in position within the elastomeric member.

30. An elastomeric member as claimed in claim 22 wherein the elastomeric member comprises a ribbed outer surface.

31. An apparatus comprising:
a plurality of components; and
an elastomeric member comprises a plurality of grooves configured to receive edge portions of the plurality of components, the plurality of grooves are configured to hold the plurality of components in position within the elastomeric member.

32. An apparatus as claimed in claim 31 further comprising a casing configured to contain the elastomeric member.

33. An apparatus as claimed in claim 31 wherein the plurality of components comprise a processor configured to execute computer program instructions.

34. An apparatus as claimed in claim 31 wherein the plurality of components comprise a circuitry.

35. An apparatus as claimed in claim 31 wherein the plurality of components comprise a display.

36. A method comprising:
arranging a plurality of components of an electronic apparatus within a plurality of grooves of an elastomeric member, wherein the grooves are configured to receive edge portions of the plurality of components and hold together the plurality of components.

37. A method as claimed in claim 36 wherein the components comprise internal components of the electronic apparatus.

38. A method as claimed in claim 36 wherein the elastomeric member is configured to extend around the perimeter of the components.

39. A method as claimed in claim 38 wherein the elastomeric member is configured to surround the perimeter of the components.

40. A method as claimed in claim 36 wherein the elastomeric member comprises a recess configured to secure the elastomeric member to a casing of the electronic apparatus.

41. A method as claimed in claim 40 wherein the elastomeric member is configured to hold the plurality of components in position within the casing of the electronic apparatus.
